(19) United States
(12) Patent Application Publication
(10) Pub. No.: US 2005/0282308 A1
(43) Pub. Date: Dec. 22, 2005

(54) Organic electroluminescent display device and method of producing the same

(76) Inventors: Albrecht Uhlig, Berlin (DE); Kerstin Nolte, Berlin (DE)

Correspondence Address: MCGUIREWOODS, LLP, 1750 TYSONS BLVD, SUITE 1800, MCLEAN, VA, 22102, US

(21) Appl. No.: 11/123,167

(22) Filed: May 6, 2005

(30) Foreign Application Priority Data
Jun. 22, 2004 (EP) 04 090 249.6
Oct. 22, 2004 (KR) KR10-2004-0084788

(51) Int. Cl. H01L 21/00; H01L 51/40; H01M 4/60; H01L 29/08

(52) U.S. Cl. 438/99; 438/82; 438/29; 429/213; 257/40

(57) ABSTRACT

The present invention provides an organic electroluminescent display device and a method of producing the device. The organic electroluminescent display device includes a substrate and multiple active areas formed on the substrate, where each active area has a first electrode, a second electrode, and an emission portion interposed between the first electrode and the second electrode and having an emission layer. In addition, the device includes a layer of a material derived from an organosilane-based material represented by Formula (1) formed on at least a part of a passive area between active areas. 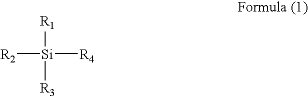
where R₁ is a fluorine atom or a C₁₋₂₀ alkyl group substituted by one or more fluorine atoms, at least one of R₂, R₃ and R₄ is a hydrolysable group, and the remainders are independently a hydrogen atom, halogen atom, C₁₋₁₀ alkyl group or C₁₋₁₀ alkoxy group.

### BACKGROUND OF THE INVENTION

This application claims the priority to and benefit of European Patent Application No. 04 09 249.6, filed on Jun. 22, 2004 in the European Intellectual Property Office and Korean Patent Application No. 10-2004-0084788, filed on Oct. 22, 2004 in the Korean Intellectual Property Office, the disclosures of which are incorporated herein in their entirety by reference.

1. Field of the Invention

The present invention relates to an organic electroluminescent display device. More particularly, the invention relates to an organic electroluminescent display device that has a layer to prevent ink overflow to neighboring active areas during inkjet printing in at least a part of a passive area between active areas. The invention also provides a method for producing the same.

2. Description of the Related Art

The inkjet printing process is one of the most important structuring processes in the production of full-color displays. Inkjet printing involves depositing small drops of a solution of semi-conducting polymers (LEPs) onto a suitable substrate. The inkjet printing process, is used in many technological areas such as in the deposition of color filters or DNA sensors onto a substrate.

All of these applications require exact placement of the substances (ink) onto an active surface. In inkjet printing, an ink is produced by the dissolving the active substance in an auxiliary substance. The resulting ink is then deposited in small quantities in drop form onto the substrate, e.g., by the piezo or “bubble jet” inkjet technique. The exact positioning of the drop on the substrate is achieved by mechanically positioning the inkjet head relative to the substrate. After evaporating the auxiliary substance, the active substance forms a film on the active surface of the substrate.

One of the most frequent problems during printing is the run-off of the ink drop from the active surface into neighboring surfaces of the substrate. For display elements containing organic light emitting diodes (OLEDs), this run-off means a mixing of colors because in these displays, red, green and blue emitting areas are arranged adjacent to each other.

OLED display elements have been used since the late 1980's. including two types known as polymer OLEDs (PLEDs) and low-molecular OLEDs (SM-OLEDs). WO 00/76008A1 describes the basic structure of a PLED display element. U.S. Pat. No. 4,539,507 and U.S. Pat. No. 4,885,211 describe the principle structure of an SM-OLED in which AlQ₃ (tris-(5-chloro-8-hydroxy-quinolinato)-aluminum) is described as an emission and electron transporting material.

The fundamental principle upon which OLED structural elements are based is electroluminescence. Using suitable contacts, electrons and holes are injected into a semiconducting material and light is released upon the recombination of these charge carriers.

Piezo inkjet printing is one of the most important structuring techniques in the production of full-color displays based on polymer OLEDs and is described in U.S. Application No. 2002/004126. In that case, small drops of a solution containing the active substance (hole transporting or emission materials) are deposited on the active surface of a suitable substrate. The dimensions of these active surfaces (single picture point/pixel) for a high-resolution display element, as used for example in modern mobile telephones, are in the range of 40 μm×180 μm.

Inkjet heads, in accordance with the state of the art, can produce ink drops with a diameter larger than 30 μm. Subsequently, the drop diameter is in the same magnitude range as the picture point to be coated. In order to prevent an overflow of the drop, the surface of the substrate is formed in basically two ways. The first method is to produce a substrate surface that has established areas with different surface energies and therefore have different covering properties for the ink. A second option is to use geometrical (mechanical) barriers that are designed to prevent an overflow of the drop.

One of the typical approaches is described in EP 0989778 A1. A contrast of surface energies is created using a suitable materials to form the substrate surface. The printed-on ink can only adhere to areas with high surface energy whereas areas with low surface energy act as a barrier. In order to obtain a homogenous film thickness the high surface energy surfaces are set beyond the periphery of the pixel surface of the organic light emitting diode (OLED). The film is then homogenous to the peripheral zone and the layer thickness noticeably reduces just outside of the active area near the barrier.

The necessary contrast of the surface energies can be achieved in many different ways. EP 0989778 A1 describes a two-layer surface structure of the surface. By means of a suitable surface treatment in the plasma, the upper layer can be provided with low surface energy whereas the lower layer, based on its chemical nature, receives high surface energy with the same treatment. Typically, the lower layer is made of inorganic materials such as silicon oxide/nitride. The inorganic layer acts as a peripheral zone with high surface energy and facilitates the deposition of homogenous polymer films using the inkjet printing process.

Depositing and structuring this layer requires processes that are used typically in the semiconductor industry. Sputter processes and gas phase processes such as PECVD (Plasma Enhanced Chemical Vapor Deposition) are suitable for the layer deposition. These processes require long pulse times and are also expensive which reduces the cost-advantage gained from using the OLED-technology. In addition, the second layer forms the surface topography meaning that the areas with low surface energy (called “separators”) are set off at finite heights from the substrate surface. As a result of this height profile, the deposited polymer film can form an undesirable thickness profile where it curves upwards into the peripheral areas at the separators. Depending on the dimensions, this upward curving can protrude into the pixels.

A further disadvantage of the technology described in EP 0989778 is that an ink reservoir is used as additional overflow protection. The fabrication of this reservoir is time-consuming and increases the technological difficulty because of the additional process step.

JP 09203803 describes the chemical treatment of a substrate surface that has previously been treated with a photoresist. Following the chemical treatment, the photoresist is exposed using a mask and then developed. In the resulting structure, the areas with photoresist have low surface energy while areas without photoresist have high surface energy. The flanks of the photoresist structure indicate a mean surface energy and, because of this, the surface can reduce the abrupt transition of the surface energies. However, the surface does not represent a boundary zone with a freely selectable surface energy and geometry. This structure is a disadvantage insofar as the spatial dissolution capacity of the inkjet printing process declines through areas with mean surface energy. A further disadvantage is the fact that only one photoresist material can be used which prevents a contrast of the surface energies that is obtained with the application of various materials, thus restricting the applicability of this method. In addition, the chemical treatment is a time-consuming process step which leads to a high production time.

JP 09230129 describes a two-stage treatment of the surface. First, the entire surface is provided with a low surface energy material. Upon the subsequent treatment of selected parts of the surface with short wavelength light, the surface energy in these areas is increased again. The obtainable contrast of the surface energy is, however, limited and the required exposure time is not compatible with a mass production.

DE 10236404.4 (assigned to Samsung SDI) describes the surface fluorination of a photoresist using a plasma process containing CF₄ in conjunction with a lift-off process for structuring. However, the CVD process required here is a vacuum-based technology that is expensive and has a high production time. Furthermore, the surface energy level set by the process as described is not stable with reference to time because the fluorinated parts of the surface diffuse into the photoresist layer in order to subsequently establish equilibrium. Another disadvantage of this process is the fact that the surface modified with fluorine is not stable against solutions containing acids such as polyethylenedioxy-thiophene/polystyrene sulfonic acid (PDOT:PSS) and is washed away by them.

DE 10334351.1 (assigned to Samsung SDI) describes the deposition of a hydrophobic layer such as Teflon™ for producing an ink-repelling function. The Teflon™ is deposited by CVD or by thermal evaporation and is structured using lift-off, laser ablation or the use of a shadow mask. Both techniques for depositing the Teflon™ are vacuum processes and, result in additional costs and time. Furthermore, in this case, there is a limit on the substrate size. Another disadvantage of DE 10334351.1 is the thermal instability of the low-energetic layer. For example, the Teflon™ named in the invention has a tendency to evaporate under normal pressure at temperatures around 150° C.

U.S. Pat. No. 6,656,611 describes using photoresists based on polysiloxane as isolating materials for the active surface of a display. The polysiloxane is preferably an “overhanging structure” so that it deposits the cathode of passive matrix displays. However, as the polysiloxane layer has a considerable thickness, the cathode layer resistance is negatively influenced by the separation of the metal film at the edges of the polysiloxane layer.

Geometrical (mechanical) barriers are described as a second option for preventing an overflow of a drop.

U.S. Pat. No. 6,388,377 B1 describes the use of photoresist stripe structures that are positioned between two neighboring picture points. These photo-resist stripes have a height of greater than 2 μm and are oriented opposite the ink drop to function as a physical barrier preventing an overflow.

The fabrication of the photo-resist structures is described in EP 0996314 A1. Two photoresist structures in each case are arranged parallel to one another (so-called “banks”) to form a channel in the center of which there are picture points that emit the same color (red, green or blue). Printing a suitable ink in this channel allows a layer of these picture points with active material to be formed while the photoresist structure simultaneously prevents an overflow to picture points which lie outside of the channel. The height of the banks is larger than 0.5×(width of the picture point/diameter of the drop). The height is also larger than the film thickness of the active material deposited using the inkjet printing technique. Applying round, oval or triangular notch indentations on the banks where these indentations serve as an overflow reservoir results in favorable configurations of the banks.

However, the disadvantage here is that the height of the banks and/or the edges leads to a quality reduction of the metal deposition in a following production step. In this metal deposition, the cathode of the OLED structural element is formed by thermal evaporation or sputtering. Based on the form and height of the photoresist structures, an interruption occurs, or at least there is a thinner separation of the metal film on the side walls of the “banks” in particular. This leads to an increased electric resistance which has a disadvantageous effect on the power input of the display element.

DE 103 11 097.6 describes the use of additional ink stoppers.

The channel structures according to U.S. Pat. No. 6,388,377 B1 are open on the upper and lower ends and prevent an ink overflow in the lateral direction only. For this reason, the ink can flow unhindered along the channels and, therefore, can flow out of the ends of these channels also. Thus, the ink volume is less at the ends of the channels than in the middle, through which a non-homogenous layer thickness distribution of the dried hole-conducting layer and polymer layer occurs along the channels, and this is also clearly evident in the electroluminescence. The above-mentioned ink stoppers prevent a run-out of the liquid ink from the upper and lower end of the channel structures.

U.S. Patent Application No. 2003/0042849 describes a further approach to defined drop positioning and film formation with displays produced by means of the inkjet printing technique. Here, a mechanical mask is positioned on the substrate so that the organic emitter can be deposited by a spin-coating technique. However, the use of metal shadow masks has a limit in the size of the substrates to be coated. Varying expansion coefficients as well as non-perfect planar masks or substrates cause a displacement where larger substrates are concerned.

In summary, the fabrication of substrates as proposed in current technologies is either too time-consuming and/or cost-intensive, the cathode deposition due to the height of the “banks” leads to an unacceptably high electrical resistance, or the substrate, particularly a large substrates, has an undesirable displacement due to the use of masks.

### SUMMARY OF THE INVENTION

The present invention provides an organic electroluminescent display device that can be produced at low costs, has a high resolution, and has low electric resistance for a second cathode. The present invention also provides a method for producing an organic electroluminescent display device that can reduce processing costs and time as compared to the conventional method and reduce the number of masks which leads to an undesirable displacement where larger substrates are concerned.

Additional features of the invention will be set forth in the description which follows, and in part will be apparent from the description, or may be learned by practice of the invention.

One aspect of the present invention provides an organic electroluminescent display device including a substrate that has multiple active areas formed on it. Each active area has a first electrode, a second electrode, an emission portion interposed between the first electrode and the second electrode, and an emission layer. The substrate also has a layer composed of a derivative of an organosilane-based material represented by Formula (1) that is formed on at least a part of a passive region between active areas.

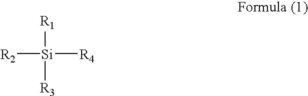

According to Formula (1), R₁ is a fluorine atom or a C₁₋₂₀ alkyl group substituted by one or more fluorine atoms or it can also be a C₅₋₁₅ alkyl group substituted by one or more fluorine atoms. At least one of R₂, R₃ and R₄ is a hydrolysable group. The hydrolysable group can be a halogen atom, amino group or C₁₋₂₀ alkoxy group. The remainders can be a hydrogen atom, halogen atom, C₁₋₁₀ alkyl group or C₁₋₁₀ alkoxy group.

Another aspect of the present invention provides a method for producing an organic electroluminescent display device that includes first forming first electrodes on a substrate, forming a layer of a material derived from an organosilane-based material represented by previously discussed Formula (1) on at least a part of a passive area between active areas of the substrate next forming an emission layer in the active area and finally forming second electrodes.

It is to be understood that both the foregoing general description and the following detailed description are exemplary and explanatory and are intended to provide further explanation of the invention as claimed.

### BRIEF DESCRIPTION OF THE DRAWINGS

The above and other features and advantages of the present invention will become more apparent by describing its exemplary embodiments with reference to the attached drawings.

FIG. 1 is a schematic cross-sectional view of an organic electroluminescent display device according to an embodiment of the present invention.

FIGS. 2, 3, 4 and 5 are schematic diagrams that illustrate a method of producing an organic electroluminescent display device according to an embodiment of the present invention.

### DETAILED DESCRIPTION OF THE INVENTION

Hereinafter, the present invention will be described in detail with reference to the attached drawings.

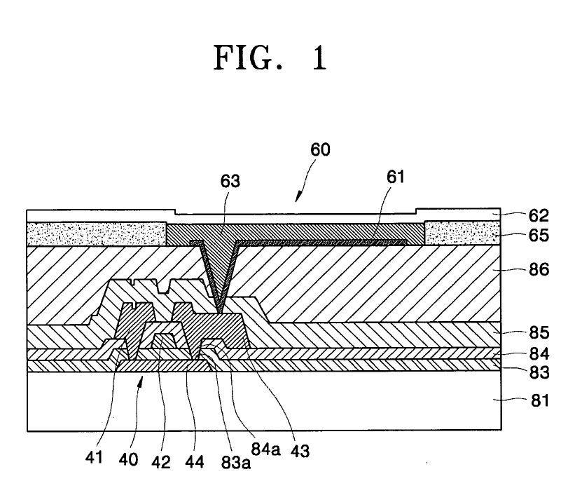

FIG. 1 is a cross-sectional view of an active matrix organic electroluminescent display device according to an embodiment of the present invention that illustrates a thin film transistor (TFT) 40 and an organic electroluminescent element 60. As shown in FIG. 1, the active matrix organic electroluminescent display device also includes a substrate 81 that may comprise glass, plastic, or silicon oxide, silicon nitride or both silicon oxide and silicon nitride.

Although it is not shown in FIG. 1, a buffer layer can be formed on the entire surface of the substrate 81.

An active layer 44 that is arranged in a predetermined pattern is formed on the substrate 81. The active layer 44 is embedded under a gate insulating layer 83. A gate electrode 42 of the TFT 40 is formed at a position corresponding to the active layer 44 on the gate insulating film 83. The gate electrode 42 is embedded under an interinsulating layer 84. After the interinsulating layer 84 is formed, the gate insulating layer 83 and the interinsulating layer 84 are etched by dry etching, etc., to form contact holes 83a and 84a, thereby exposing a part of the active layer 44.

The exposed portion of the active layer 44 is connected to a source electrode 41 and a drain electrode 43 of the driving TFT 40 formed in a predetermined pattern at both sides through the contact holes 83a and 84a. The source electrode 41 and the drain electrode 43 are embedded in a protecting layer 85. After the protecting layer 85 is formed, a part of the drain electrode 43 is exposed through an etching process.

The protecting layer 85 is composed of an insulating material. The protecting layer 85 may be an inorganic film of silicon oxide or silicon nitride or an organic film of acrylic or benzocyclobutene (BCB). An additional insulating layer 86 for planarizing the protecting layer 85 can be formed on the protecting layer 85. The insulating film 86 may be an inorganic film of silicon oxide or silicon nitride or an organic film of acryl or BCB.

The organic electroluminescent element 60 displays image data by emitting red, green and blue light according to the flow of current. The organic electroluminescent element 60 includes a first electrode 61 as a pixel electrode connected to the drain electrode 43 of the TFT 40 and a second electrode 62 as a counter electrode covering the entire pixel. In addition, it includes an organic emission layer 63 disposed between the first electrode 61 and the second electrode 62 where at least a part of the organic emission layer 63 can be formed using an inkjet printing technique. The first electrode 61 and the second electrode 62 are isolated from each other and apply different polar voltages to the organic emission layer 63, thereby emitting light.

The first electrode 61 can be provided as a transparent electrode or reflective electrode. When it is used as a transparent electrode, it may be composed of Indium Tin Oxide (ITO), Indium Zinc Oxide (IZO), ZnO or In₂O₃. When it is used as a reflective electrode, it may have a reflective layer composed of Ag, Mg, Al, Pt, Pd, Au, Ni, Nd, Ir, Cr or a mixture thereof and a transparent electrode layer thereon with ITO, IZO, ZnO or In₂O₃.

The organic electroluminescent display device of the present embodiment includes a layer 65 of a material derived from an organosilane-based material represented by previously mentioned Formula (1):

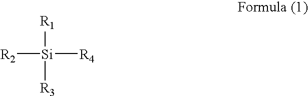

According to Formula (1), R₁ is a fluorine atom or a C₁₋₂₀ alkyl group substituted by one or more fluorine atoms or it can also be a C₅₋₁₅ alkyl group substituted by one or more fluorine atoms. At least one of R₂, R₃ and R₄ is a hydrolysable group. The hydrolysable group can be a halogen atom, amino group or C₁₋₂₀ alkoxy group. The remainders can be a hydrogen atom, halogen atom, C₁₋₁₀ alkyl group or C₁₋₁₀ alkoxy group.

Preferably, the layer of the organosilane-based material is produced using (a compound represented by Formula (1)) 1H, 1H, 2H, 2H-perfluorooctyltriethoxysilane or (hepta-decafluoro-1,1,2,2-tetrahydrodecyl) dimethyl chlorosilane.

This invention is based on the concept of creating regions with contrasting low and high surface energy levels using self-organizing structures on the substrate. The substrate surface according to the invention includes active areas for accommodating organic (emitter-) material for the formation of picture points (pixels) and passive areas for the separation of the pixels. The passive areas segregate and/or separate the individual active areas from each other and, as a result, ensure that the different inks for the individual colors (red, green, blue) do not mix during the imprinting of the substrate with organic emitter material.

In an embodiment of the present invention, the layer of the material derived from the organosilane-based material is covalently bonded to the insulating layer 86 or, if the insulating layer 86 is not formed, to the protecting layer 85.

In another embodiment of the present invention, the surface energy of the layer of the material derived from the organosilane-based material is lowered by a chemical modification. This material preferably has a fluorine atom or C₁₋₂₀ alkyl group substituted by one or more fluorine atoms. Thus, the layer of the material derived from the organosilane-based material 65 may have a surface energy smaller than 40 mJ/m².

Referring to FIG. 1, the emission layer 63 can easily be formed using a printing technique, such as inkjet printing. The organic emission layer 63 can be composed of low molecular weight or high molecular weight organic materials. When a low molecular weight organic material is used, a hole injection layer (HIL), a hole transport layer (HTL), an emission layer (EML), an electron transport layer (ETL), an electron injection layer (EIL), etc. can be stacked to form a single or composite structure. Examples of the organic materials may include but are not limited to copper phthalocyanine (CuPc), N, N-di(naphthalene-1-yl)-N, N′-diphenyl-benzidine (NPB), tris-8-hydroxyquinoline aluminum (Alq3) and the like.

When using a high molecular weight organic material, a structure having an HTL and an EML can be formed. In that case, poly(3,4-ethylene dioxythiophene (PEDOT) is used as the HTL and poly-phenylenevinylene- and polyfluorene-based materials, etc. are used as the EML. These layers can be formed by a screen printing or inkjet printing. However, the organic emission layer is not limited to the mentioned compositional materials and various embodiments can be applied.

As for the first electrode, the second electrode 62 can also be provided as a transparent electrode or reflective electrode. Since the second electrode 62 is used as a cathode, a metal with low work function such as Li, Ca, LiF/Ca, LiF/Al, Al, Ag, Mg or a combination thereof is deposited on the organic emission layer 63. When it is used as a transparent electrode, the metal is first deposited onto the organic emission layer 63, and then an auxiliary electrode layer or bus electrode line of ITO, IZO, ZnO or In₂O₃ can be formed thereon. When it is used as a reflective electrode, Li, Ca, LiF/Ca, LiF/Al, Al, Ag, Mg or a combination thereof is deposited on active areas.

The first electrode 61 can act as an anode and the second electrode 62 can act as a cathode, or vice versa. The first electrode 61 can be patterned corresponding to the individual active areas and the second electrode 62 can be formed so as to cover the entire active areas.

In addition, a protective layer, etc. can be formed on the second electrode 62.

Although the active matrix organic electroluminescent display device has been described as an example of the present invention, various modifications including but not limited to a passive matrix organic electroluminescent display device having a stripe-type first electrode and a stripe-type second electrode extending perpendicularly to the first electrode are possible.

A method of fabricating the organic electroluminescent display device according to an exemplary embodiment includes forming a first electrode on a substrate, forming a layer of a material derived from an organosilane-based material represented by Formula (1) on at least a part of a passive area between active areas of the substrate, forming an emission layer in the active area, and forming second electrodes.

In an active matrix organic electroluminescent display device, the substrate 20 can include, for example, transistors and a layer for planarization composed of but not limited to silicon oxide or silicon nitride.

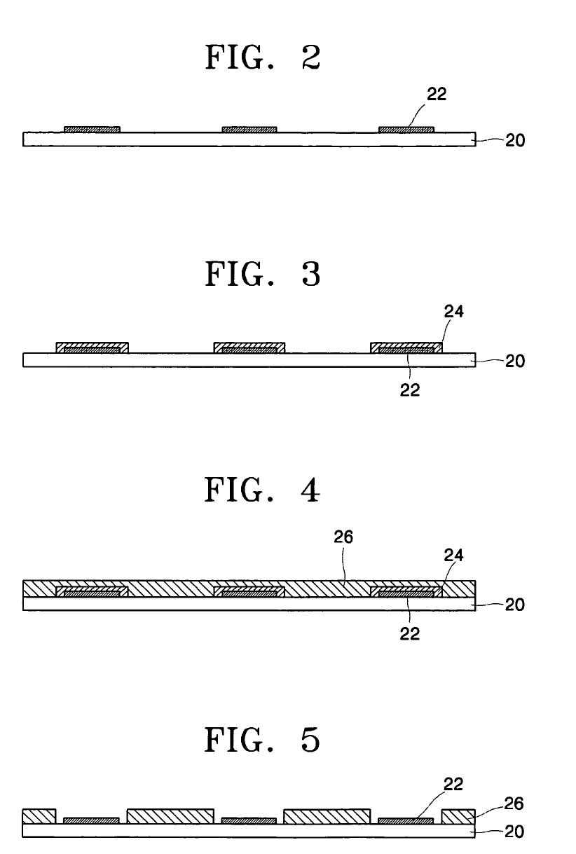

The process of forming the first electrode and the layer of the material derived from the organosilane-based material represented by Formula (1) is described in more detail with reference to FIG. 2, FIG. 3, FIG. 4, and FIG. 5.

FIG. 2 illustrates forming a first electrode 22 on a substrate 20. The first electrode can be formed using various deposition methods. It can be composed of a transparent conductive material such as ITO and have various shapes such as stripe-type and mesh-type. When producing an active matrix organic electroluminescent display device, the first electrode should be electrically connected to a source electrode or drain electrode of a transistor included in the substrate.

FIG. 3 illustrates forming a photoresist 24 that covers at least a part of the first electrode 22 on the substrate 20. The formation method of the photoresist is not particularly limited and one of ordinary skill in the art may know such methods. Various modifications are possible, for example, the entire of the first electrode 22 can be covered as in FIG. 3, or only a part of the first electrode 22 can be covered.

For example, structuring the layer of the material derived from the organosilane-based material represented by Formula (1) can preferably be performed using a lift-off process. This process includes first forming a photoresist to cover at least a part of the first electrode so that the active surfaces are covered and the passive surfaces are not covered.

FIG. 4 illustrates the next step of forming a layer 26 of the material derived from the organosilane-based material represented by Formula (1) on the entire surface of the substrate 20 that has a partial photoresist cover. The layer of a material 26 derived from an organosilane-based material represented by Formula (1) is preferably deposited using a wet-chemical mixture containing the organosilane-based material to the substrate 20 having the first electrode 22 and the photo-resist 24 and curing the mixture. The mixture may comprise, for example, organosilane-based material represented by Formula (1) and a solvent such as ethanol. This ensures low process costs because the solution can be recycled several times and additional active material (organosilane-based material) can be combined if necessary to bring the solution up to the required concentration.

This results in a layer of a material derived from an organosilane-based material represented by Formula (1) is formed in the passive area between active areas of the substrate. Thus, passive areas of low surface energy are formed in a pattern on the substrate so that they separate the active areas (surfaces) on which the pixel points are arranged from one another. The low surface energy of the passive areas allows for a contrast of the surface energy. In one exemplary embodiment, the surface energy of the layer is lowered by chemical modification such that the layer includes a fluorine atom or C₁₋₂₀ alkyl group substituted by one or more fluorine atoms.

In the last step of the lift-off process, the photoresist and the organosilane-based material layer in the zone of the photoresist are removed. FIG. 5 illustrates removing the photoresist 24 (see FIG. 4). The photoresist can be removed by a standard method where the photoresist and the layer formed on the photoresist are removed together. In this way, as illustrated in FIG. 5, the layer of the material derived from the organosilane-based material represented by Formula (1) is formed in a passive area and the passive areas can segregate active areas at least in a part of which the first electrode 22 is formed.

This process results in a non-continuous layer of the material derived from the organosilane-based material of Formula (1) being formed in the passive areas. This is achieved at a very favorable cost with a high contrast in the surface energy. In addition to this process, further required steps such as the wet-chemical substrate cleaning can be carried out without a change in the contrast of the surface energies. Because of the covalent bonds between the material derived from the organosilane-based material represented by Formula (1) and the substrate, the layer is significantly more thermally stable than, for example, a Teflon™ layer, and this property is important for follow-up process steps.

After the completion of the lift-off process, an emission layer is formed in the active area by means of various printing techniques such as an inkjet printing technique and second electrodes are formed.

The present invention will now be described in greater detail with reference to the following examples. The following examples are for illustrative purposes only and are not intended to limit the scope of the invention.

### EXAMPLE 1

A 1.1 mm thick boron silicate glass substrate was prepared. One or more transistors having one or more semiconducting materials, source electrodes and drain electrodes were provided in the substrate. An ITO layer was formed on the substrate as a first electrode.

Then, a 0.3 μm thick photoresist (JEM 750) was applied to this substrate using standard techniques so that the ITO layer was covered and passive areas were not covered. Then, the substrate was cleaned for 5 minutes in an ultrasonic isopropanol bath and, after drying by blowing with nitrogen, a UV-ozone treatment was performed for 10 minutes.

Thereafter, a solution of 10% 1H, 1H, 2H, 2H-perfluorooctyltriethoxysilane C₁₄H₁₉F₁₃O₃Si (Gelest, Inc.) dissolved in ethanol of Roth (>96%, DAB) was prepared. The substrate was immersed in the solution. After drying in the air, the substrate is tempered for 30 minutes at 160° C. on a heating plate in air.

Then, the photoresist was removed with tetrahydrofuran (THF) to obtain a substrate having active areas with the ITO layer provided on at least a part thereof and passive areas of the hydrolysate of 1H, 1H, 2H, 2H-perfluorooctylethoxysilane.

### EXAMPLE 2

A substrate was prepared in the same manner as in Example 1, except that (hepta-decafluoro-1,1,2,2-tetrahydrodecyl) dimethyl chlorosilane was used instead of 1H,1H,2H,2H-perfluorooctylethoxysilane.

Keeping the thickness of the repelling layer relatively low (in the zone of mono layers) allows for a substrate used in the inkjet printing technique to have a very small profile. This characteristic has an advantageous effect on the power input of an active matrix OLED because of a very low cathode resistance.

Conventional surfaces used in inkjet-printed structural elements have profiles with height differences ranging from about 100 nm up to a few microns. These edges cause non-homogenous metal cathode deposition during the cathode film preparation processes such as thermal evaporation or sputtering. As a result, the deposition of the metal on these edges becomes disturbed and the cathode layer becomes thinner or may even tear off completely. This usually occurs with substrates that have edge profiles that are more than 300 nm high. This causes an increase in the ohmic resistance of the cathode which subsequently leads to increased power input or a structural malfunction.

The relatively small height of a layer of the material derived from the organosilane-based material represented by Formula (1) as described in the present invention is advantageous for use in high-resolution structural elements and for the production of flat films. The reason for this is that the distance required for the segregation of two active surfaces and, subsequently, for avoiding an overflow of the ink, can be reduced significantly. Generally, when using photoresist structures as separators, the minimum height, for reason of stabilization, is approximately 10 μm.

With the invention presented here, however, the minimal width is limited by the resolution of the lithography that defines the lift-off structures, or by the otherwise applied structuring methods. This invention allows a minimal width of less than 10 μm. The space that can be saved by this invention can be used for increasing the resolution and/or for increasing the filling factor (ratio of active surface of a pixel to the entire pixel surface) and/or for reducing the layer thickness variations of the inkjet-printed material. The latter effect is caused by the drying behavior of the ink at boundary surfaces with strong contrast in the surface energies.

The use of a material with low surface energy from the class of the organic materials allows for a simple structuring technology. This is in contrast to approaches where inorganic layers such as SiO₂ are applied for producing surfaces with high surface energy.

In summary, an organic electroluminescent display device and methods of producing the same according to embodiments of the present invention have several advantages.

First, the surface for inkjet printing have high contrast in the surface energies because of the selection of materials that have a predefined surface energy. In addition, the avoidance of using inorganic materials in more complicated structuring techniques and the use of the plain wet-chemical deposition technology allows low process costs and avoids a vacuum process and further surface treatments for producing the contrast of the surface energies.

Other advantageous properties of the present invention include the stability of the layer of the material derived from the organosilane-based material represented by Formula (1) against thermal treatment, the use of a layer system with low surface profile to avoid the second cathode separation effects due to the layer of the material derived from the organosilane-based material represented by Formula (1), and a small width between the active surfaces. Such a device is suitable for high-resolution printing and provides a larger filling factor for OLEDs or printed color filters and/or higher layer thickness homogeneity in the active surface for OLEDs or printed color filters.

While the present invention has been particularly shown and described with reference to exemplary embodiments thereof, it will be understood by those of ordinary skill in the art that various changes in form and details may be made therein without departing from the spirit and scope of the present invention as defined by the following claims. Thus, it is intended that the present invention cover the modifications and variations of this invention provided they come within the scope of the appended claims and their equivalents.

1. An organic electroluminescent display device, comprising:
a substrate;
a plurality of active areas formed on the substrate; and
a layer of a material derived from an organosilane-based material represented by Formula (1) formed on at least a part of a passive area between the active areas; and 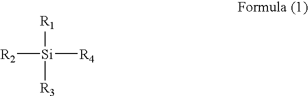
an emission layer,
wherein each active area has a first electrode, a second electrode, and an emission portion interposed between the first electrode and the second electrode,
wherein R₁ in Formula (1) is a fluorine atom or a C₁₋₂₀ alkyl group substituted by one or more fluorine atoms, and
wherein at least one of R₂, R₃ and R₄ is a hydrolysable group and the remainders are independently a hydrogen atom, halogen atom, C₁₋₁₀ alkyl group or C₁₋₁₀ alkoxy group.

2. The organic electroluminescent display device of claim 1, wherein R₁ is a C₅₋₁₅ alkyl group substituted by one or more fluorine atoms.

3. The organic electroluminescent display device of claim 1, wherein the hydrolysable group is a halogen atom, amino group, or C₁₋₂₀ alkoxy group.

4. The organic electroluminescent display device of claim 1, wherein the material represented by Formula (1) is 1H, 1H, 2H, 2H-perfluorooctyltriethoxysilane or (hepta-decafluoro-1,1,2,2-tetrahydrodecyl) dimethyl chlorosilane.

5. The organic electroluminescent display device of claim 1, wherein the material derived from the organosilane-based material represented by Formula (1) is covalently bonded to the substrate.

6. The organic electroluminescent display device of claim 1, wherein the surface energy of the material derived from the organosilane-based material represented by Formula (1) is 40 mJ/m² or less.

7. The organic electroluminescent display device of claim 1, wherein the substrate comprises silicon oxide, silicon nitride or both thereof.

8. The organic electroluminescent display device of claim 1, wherein the first electrode comprises at least one selected from the group consisting of Indium Tin Oxide (ITO), Indium Zinc Oxide (IZO), ZnO, and In₂O₃.

9. The organic electroluminescent display device of claim 1, wherein the second electrode comprises at least one selected from the group consisting of Al, Ag, and Mg.

10. The organic electroluminescent display device of claim 1, wherein at least a part of the emission layer is formed by inkjet printing.

11. A method for producing an organic electroluminescent display device, comprising:
forming a first electrode on a substrate;
forming a layer of a material derived from an organosilane-based material represented by the following Formula (2) on at least a part of a passive area between active areas of the substrate; 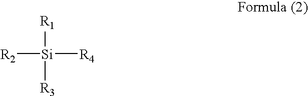
forming an emission layer in the active area; and
forming a second electrode,
wherein R₁ in Formula (2) is a fluorine atom or a C₁₋₂₀ alkyl group substituted by one or more fluorine atoms; and
wherein at least one of R₂, R₃ and R₄ is a hydrolysable group and the remainders are independently a hydrogen atom, halogen atom, C₁₋₁₀ alkyl group or C₁₋₁₀ alkoxy group.

12. The method of claim 11, wherein R₁ is a C₅₋₁₅ alkyl group substituted by one or more fluorine atoms.

13. The method of claim 11, wherein the hydrolysable group is a halogen atom, amino group or C₁₋₂₀ alkoxy group.

14. The method of claim 11, wherein the material represented by Formula (2) is 1H, 1H, 2H, 2H-perfluorooctyltriethoxysilane or (hepta-decafluoro-1,1,2,2-tetrahydrodecyl) dimethyl chlorosilane.

15. The method of claim 11, wherein forming a layer of the material derived from the organosilane-based material represented by Formula (2) in at least a part of passive areas between active areas of the substrate, comprises:
forming a photoresist so as to cover at least a part of the first electrode;
applying a mixture containing the organosilane-based material represented by Formula (2) on the entire surface of the substrate; and
removing the photoresist.

16. The method of claim 11, wherein forming an emission layer is done by inkjet printing.
